(19) United States
(12) Patent Application Publication
(10) Pub. No.: US 2015/0355486 A1
(43) Pub. Date: Dec. 10, 2015

(54) Liquid Crystal Display Panel, Thin Film Transistor Array Substrate and Color Filter Substrate

(71) Applicant: Shenzhen China Star Optoelectronics Technology Co., Ltd., Shenzhen (CN)

(72) Inventor: Mei Xiong, Shenzhen City (CN)

(21) Appl. No.: 14/367,232

(22) PCT Filed: Jun. 4, 2014
(86) PCT No.: PCT/CN2014/079190

§ 371 Date: Jun. 19, 2014

(51) Int. Cl. G02F 1/1368; H01L 27/12; G02F 1/1333; G02F 1/1335; G02F 1/1343

(52) U.S. Cl. CPC G02F 1/1368; G02F 1/133514; G02F 1/133512; G02F 1/13439; G02F 1/133345; H01L 27/1218

(57) ABSTRACT

The invention discloses a LCD panel including a display substrate. The display substrate includes a transparent substrate, pixel units, dummy pixel units, and a first wall. The transparent substrate includes a visual region, a dummy pixel setting region located outside the visible region, and a frame glue setting region located outside the dummy pixel setting region. The pixel units are disposed on the transparent substrate in the visual region. The dummy pixel units are disposed on the transparent substrate in the dummy pixel setting region. The first wall is set on the transparent substrate between the dummy pixel setting region and the frame glue setting region. The invention avoids the abnormal situation happening when coating the frame glue in the frame glue setting region, avoids the problems caused by the difficulty in controlling the accuracy of an alignment film, e.g. Mura, and improves the product yield.

### BACKGROUND OF THE INVENTION

1. Field of the Invention

The present invention relates to the technical field of liquid crystal display (LCD), and more particularly, to a LCD panel, a thin film transistor (TFT) array substrate and a color filter (CF) substrate.

2. Description of Related Art

A LCD device has the advantages of low power consumption, good image quality, small size, and light weight, so as to be popular and become the mainstream in the display field. Generally, the LCD device mainly includes a LCD panel and a backlight module. The backlight module is used to provide sufficient brightness to the LCD panel, so that the LCD panel to display images.

The LCD panel typically includes a TFT array substrate, a CF substrate disposed opposite the TFT array substrate, and a liquid crystal layer between the two substrates. The CF substrate and the TFT array substrate each include an alignment film (Polyimide, PI). The PI layers are used in liquid crystal alignment to give the liquid crystal cells an initial angle. The PI layer is generally produced by liquid flow method. It is not easy to control the PI liquid in the terminal region, so that the PI liquid can easily spill, resulting in waste. Because of the overflow of the PI liquid, the glue coating on a frame is also affected, such as the glue covers the PI liquid, making the glue adhesion affected, resulting in deterioration of stability of the LCD panel.

### SUMMARY OF THE INVENTION

In order to solve the above problems, an object of the invention is to provide a LCD panel comprising a display substrate. The display substrate includes a transparent substrate, a plurality of pixel units, a plurality of dummy pixel units, and a first wall. The transparent substrate includes a visual region, a dummy pixel setting region located outside the visible region, and a frame glue setting region located outside the dummy pixel setting region. The pixel units are disposed on the transparent substrate in the visual region. The dummy pixel units are disposed on the transparent substrate in the dummy pixel setting region. The first wall is set on the transparent substrate between the dummy pixel setting region and the frame glue setting region.

Further, the size of the dummy pixel unit and the size of the pixel unit are the same.

Further, the display substrate is a TFT array substrate. The TFT array substrate includes a plurality of thin film transistors and a peripheral circuit. The thin film transistors are disposed between the transparent substrate and the pixel units in the visible region. The peripheral circuit is disposed on the transparent substrate between the visible region and the dummy pixel setting region.

Further, the LCD panel comprises another display substrate. The another display substrate is a CF substrate. The CF substrate comprises another transparent substrate, a plurality of light-shielding units, a transparent conductive film, an insulating layer and a second wall. The light-shielding units are disposed on the another transparent substrate, and each of the light-shielding units corresponds to a position between two of the pixel units. The transparent conductive film is disposed on the light-shielding units. The insulating layer is disposed between the transparent conductive film and the light-shielding units. The second wall is set on the another transparent substrate and corresponds to a position between the dummy pixel setting region and the frame glue setting region.

Further, the display substrate is a CF substrate. The CF substrate includes a plurality of light-shielding units and a transparent conductive film. The light-shielding units are disposed between the transparent substrate and the pixel units, and each of the light-shielding units corresponds to a position between two of the pixel units. The transparent conductive film is disposed on the pixel units.

Further, the LCD panel comprises another display substrate. The another display substrate is a TFT array substrate. The TFT array substrate comprises another transparent substrate, a plurality of thin film transistors, a peripheral circuit, and a second wall. The thin film transistors are disposed on the another transparent substrate and corresponds to the visual region. The peripheral circuit is disposed on the another transparent substrate and corresponds to a position between the visual region and the dummy pixel setting region. The second wall is set on the another transparent substrate and corresponds to a position between the dummy pixel setting region and the frame glue setting region.

Another object of the invention is to provide a TFT array substrate comprising a transparent substrate, a plurality of pixel units, a plurality of dummy pixel units, and a first wall. The transparent substrate includes a visual region, a dummy pixel setting region located outside the visible region, and a frame glue setting region located outside the dummy pixel setting region. The pixel units are disposed on the transparent substrate in the visual region. The dummy pixel units are disposed on the transparent substrate in the dummy pixel setting region. The first wall is set on the transparent substrate between the dummy pixel setting region and the frame glue setting region.

Further, the TFT array substrate comprises a plurality of thin film transistors and a peripheral circuit. The thin film transistors are disposed between the transparent substrate and the pixel units in the visual region. The peripheral circuit is disposed on the transparent substrate between the visual region and the dummy pixel setting region.

Another object of the invention is to provide a CF substrate comprising a transparent substrate, a plurality of pixel units, a plurality of dummy pixel units, and a first wall. The transparent substrate includes a visual region, a dummy pixel setting region located outside the visible region, and a frame glue setting region located outside the dummy pixel setting region. The pixel units are disposed on the transparent substrate in the visual region. The dummy pixel units are disposed on the transparent substrate in the dummy pixel setting region. The first wall is set on the transparent substrate between the dummy pixel setting region and the frame glue setting region.

Further, the CF substrate comprises a plurality of light-shielding units and a transparent conductive film. The light-shielding units are disposed between the transparent substrate and the pixel units, and each of the light-shielding units corresponds to a position between two of the pixel units. The transparent conductive film is disposed on the pixel units.

The present invention prevents the PI liquid from overflow to the frame glue setting region by setting the first wall between the dummy pixel setting region and the frame glue setting region when forming an alignment film (Polyimide, PI) in the visual region. It avoids the abnormal situation happening when coating the frame glue in the frame glue setting region and the waste of the PI liquid, and improves the stability of the LCD panel. Moreover, by setting the dummy pixel setting region and the dummy pixel units in the dummy pixel setting region, the present invention greatly improves the accuracy in controlling PI, avoids the problems caused by the difficulty in controlling the accuracy of PI, e.g. Mura, and improves the product yield.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a top view of a LCD panel according to the present invention.

FIG. 2 is a cross-sectional view of a LCD panel according to the first embodiment of the present invention.

FIG. 3 is a cross-sectional view of a LCD panel according to the second embodiment of the present invention.

FIG. 4 is a cross-sectional view of a LCD panel according to the third embodiment of the present invention.

FIG. 5 is a cross-sectional view of a LCD panel according to the fourth embodiment of the present invention.

### DESCRIPTION OF THE EMBODIMENTS

Following exemplary embodiments with reference of figures are only used for describing the disclosure in detail. However, the disclosure can also be achieved through different implementations, which is not limited to the following embodiments. In the figures referred to herein, sizes and relative sizes of different layers are probably exaggerated for clarity of illustration and are not necessarily drawn to scale.

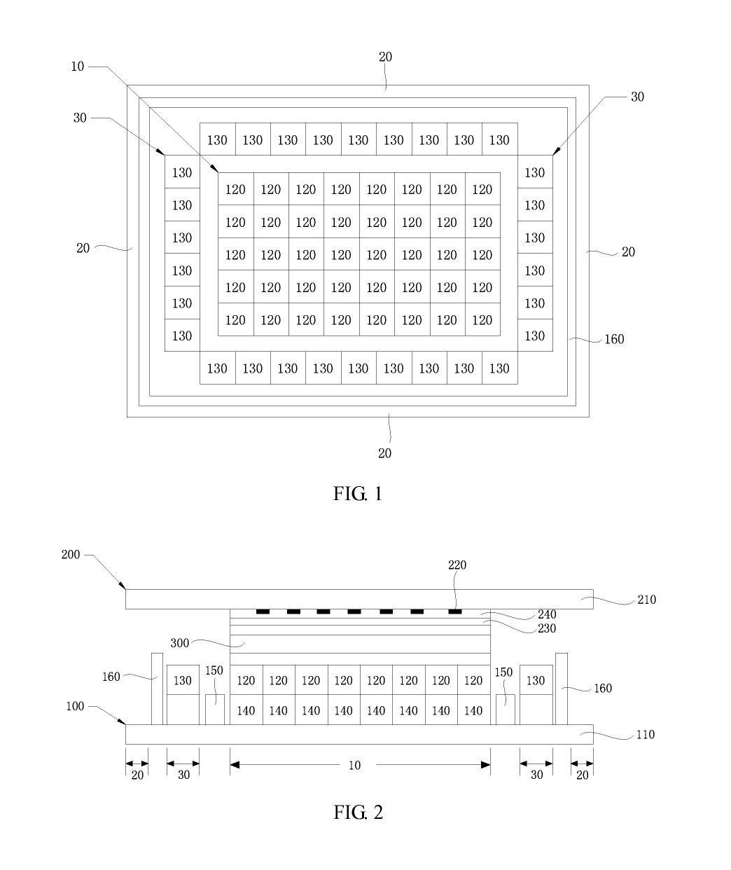

FIG. 1 is a top view of a LCD panel according to the present invention.

Please refer to FIG. 1, the LCD panel according to the present invention includes a display substrate. The display substrate includes a transparent substrate, a plurality of pixel units 120, a plurality of dummy pixel units 130, and a first wall 160. The transparent substrate includes a visual region 10, a dummy pixel setting region 30 located outside the visible region 10, and a frame glue setting region 20 located outside the dummy pixel setting region 30. The frame glue setting region 20 is used for coating the frame glue (not shown) or bonding the frame glue in a vacuum lamination process of a liquid crystal substrate. Moreover, the pixel unit 120 has a red (R) sub-pixel unit, a green (G) sub-pixel unit, and a blue (B) sub-pixel unit. The dummy pixel unit 130 also has a red (R) sub-pixel unit, a green (G) sub-pixel unit, and a blue (B) sub-pixel unit.

The pixel units 120 are disposed on the transparent substrate in the visual region 10. In other words, the visual region 10 is surrounded by the pixel units 120 disposed on the transparent substrate. The dummy pixel units 130 are disposed on the transparent substrate in the dummy pixel setting region 30. The first wall 160 is set between the dummy pixel setting region 30 and the frame glue setting region 20.

In the invention, the dummy pixel units 130 refer to the pixel units having no display function in the visible region 10, and the materials and the process of the dummy pixel units 130 are the same with those of the pixel units 120. Furthermore, in the invention, the pixel units 120 and the dummy pixel units 130 can be made at the same time, but the present invention is not limited thereto. For example, the pixel units 120 and the dummy pixel units 130 can also be made respectively at the different times. To apply the mask used in the process making the pixel units 120 to produce the dummy pixel units 130, avoiding designing another mask, preferably, the size of the dummy pixel unit 130 is the same with the size of the pixel unit 120, but the present invention is not limited thereto. For example, in the case that the pixel units 120 and the dummy pixel units 130 are made respectively at the different times, another mask can be designed to produce the dummy pixel units 130 which have arbitrary size and meet the requirements.

The present invention prevents the PI liquid from overflow to the frame glue setting region 20 by setting the first wall 160 between the dummy pixel setting region 30 and the frame glue setting region 20 when forming an alignment film (Polyimide, PI) in the visual region 10. It avoids the abnormal situation happening when coating the frame glue in the frame glue setting region 20 and the waste of the PI liquid, and improves the stability of the LCD panel. Moreover, by setting the dummy pixel setting region 30 and the dummy pixel units 130 in the dummy pixel setting region 30, the present invention greatly improves the accuracy in controlling PI, avoids the problems caused by the difficulty in controlling the accuracy of PI, e.g. Mura, and improves the product yield.

### The First Embodiment

FIG. 2 is a cross-sectional view of a LCD panel according to the first embodiment of the present invention.

Please refer to FIG. 2, the LCD panel according to the first embodiment of the present invention includes a TFT array substrate 100, a CF substrate 200 disposed opposite the TFT array substrate 100, and a liquid crystal layer 300 between the TFT array substrate 100 and the CF substrate 200.

The TFT array substrate 100 comprises a transparent substrate (for example, a glass substrate) 110, a plurality of pixel units 120, a plurality of dummy pixel units 130, and a first wall 160. The transparent substrate 110 includes a visual region 10, a dummy pixel setting region 30 located outside the visible region 10, and a frame glue setting region 20 located outside the dummy pixel setting region 30. The frame glue setting region 20 is used for coating the frame glue (not shown) or bonding the frame glue in a vacuum lamination process of a liquid crystal substrate. Moreover, the pixel unit 120 has a red (R) sub-pixel unit, a green (G) sub-pixel unit, and a blue (B) sub-pixel unit. The dummy pixel unit 130 also has a red (R) sub-pixel unit, a green (G) sub-pixel unit, and a blue (B) sub-pixel unit.

The pixel units 120 are disposed on the transparent substrate 110 in the visual region 10. In other words, the visual region 10 is surrounded by the pixel units 120 disposed on the transparent substrate 110. The dummy pixel units 130 are disposed on the transparent substrate 110 in the dummy pixel setting region 30. The first wall 160 is set between the dummy pixel setting region 30 and the frame glue setting region 20.

In the invention, the dummy pixel units 130 refer to the pixel units having no display function in the visible region 10, and the materials and the process of the dummy pixel units 130 are the same with those of the pixel units 120. Furthermore, in the invention, the pixel units 120 and the dummy pixel units 130 can be made at the same time, but the present invention is not limited thereto. For example, the pixel units 120 and the dummy pixel units 130 can also be made respectively at the different times. To apply the mask used in the process making the pixel units 120 to produce the dummy pixel units 130, avoiding designing another mask, preferably, the size of the dummy pixel unit 130 is the same with the size of the pixel unit 120, but the present invention is not limited thereto. For example, in the case that the pixel units 120 and the dummy pixel units 130 are made respectively at the different times, another mask can be designed to produce the dummy pixel units 130 which have arbitrary size and meet the requirements.

Further, the TFT array substrate 100 comprises a plurality of thin film transistors 140 and a peripheral circuit 150. The thin film transistors 140 are disposed between the transparent substrate 100 and the pixel units 120 in the visual region 10. The peripheral circuit 150 is disposed on the transparent substrate 110 between the visual region 10 and the dummy pixel setting region 30.

The CF substrate 200 includes a transparent substrate (e.g. a glass substrate) 210, a plurality of light-shielding units (e.g. black matrix) 220, and a transparent conductive film (e.g. an ITO conductive film) 230. The light-shielding units 220 are disposed on the transparent substrate 210, and each of the light-shielding units 220 corresponds to a position between two of the pixel units 120 of the TFT panel 100. The transparent conductive film 230 is disposed on the light-shielding units 220, and usually, an insulating layer 240 is disposed between the transparent conductive film 230 and the light-shielding units 220.

The first embodiment of the present invention prevents the PI liquid from overflow to the frame glue setting region 20 by setting the first wall 160 between the dummy pixel setting region 30 and the frame glue setting region 20 when forming an alignment film (Polyimide, PI) in the visual region 10. It avoids the abnormal situation happening when coating the frame glue in the frame glue setting region 20 and the waste of the PI liquid, and improves the stability of the LCD panel. Moreover, by setting the dummy pixel setting region 30 and the dummy pixel units 130 in the dummy pixel setting region 30, the present invention greatly improves the accuracy in controlling PI, avoids the problems caused by the difficulty in controlling the accuracy of PI, e.g. Mura, and improves the product yield.

### The Second Embodiment

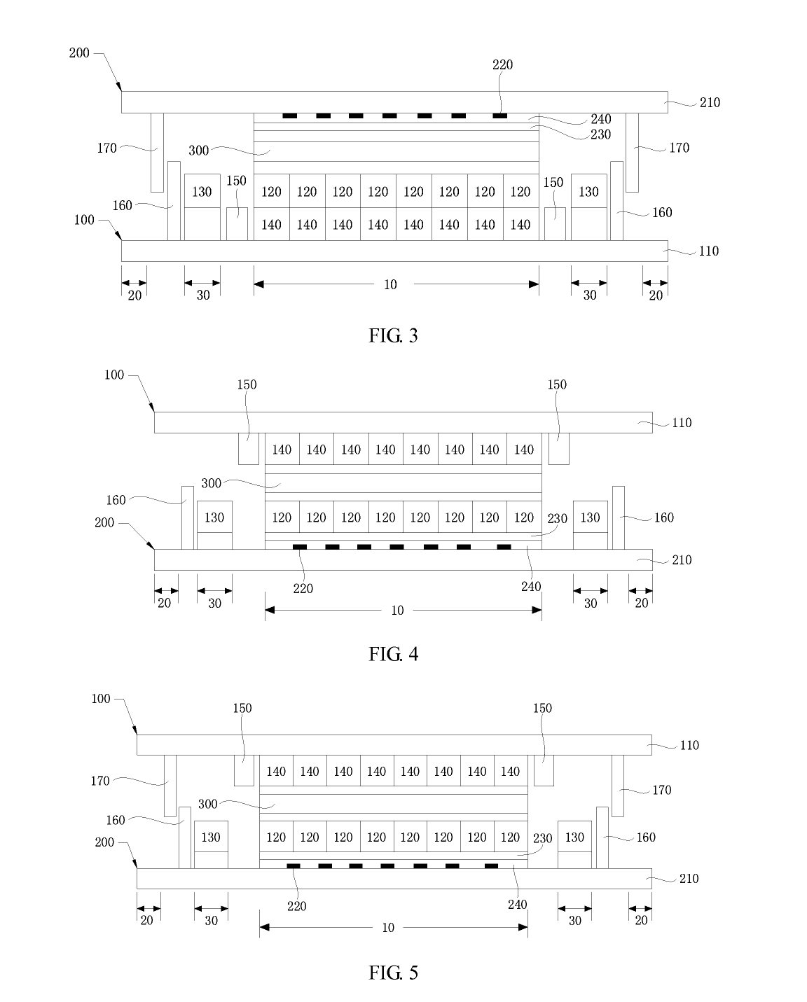

FIG. 3 is a cross-sectional view of a LCD panel according to the second embodiment of the present invention.

Please refer to FIG. 3, the difference with the LCD panel according to the first embodiment of the present invention is described as below:

In the LCD panel according to the second embodiment of the present invention, the CF substrate 200 further comprises a second wall 170. The second wall is set on the transparent substrate 210 and corresponds to a position between the dummy pixel setting region 30 and the frame glue setting region 20 of the transparent substrate 110 of the TFT substrate 100. When the TFT substrate 100 and the CF substrate 200 are bonded together, the first wall 160 and the second wall 170 are staggered so as to enhance the capacity to block the PI liquid from spilling to the frame glue setting region 20.

### The Third Embodiment

Please refer to FIG. 4, the LCD panel according to the third embodiment of the invention includes a TFT array substrate 100, a CF substrate 200 disposed opposite the TFT array substrate 100, and a liquid crystal layer 300 between the TFT array substrate 100 and the CF substrate 200.

The CF substrate 200 comprises a transparent substrate (for example, a glass substrate) 210, a plurality of pixel units 120, a plurality of dummy pixel units 130, and a first wall 160. The transparent substrate 210 includes a visual region 10, a dummy pixel setting region 30 located outside the visible region 10, and a frame glue setting region 20 located outside the dummy pixel setting region 30. The frame glue setting region 20 is used for coating the frame glue (not shown) or bonding the frame glue in a vacuum lamination process of a liquid crystal substrate. Moreover, the pixel unit 120 has a red (R) sub-pixel unit, a green (G) sub-pixel unit, and a blue (B) sub-pixel unit. The dummy pixel unit 130 also has a red (R) sub-pixel unit, a green (G) sub-pixel unit, and a blue (B) sub-pixel unit.

The pixel units 120 are disposed on the transparent substrate 210 in the visual region 10. In other words, the visual region 10 is surrounded by the pixel units 120 disposed on the transparent substrate 210. The dummy pixel units 130 are disposed on the transparent substrate 210 in the dummy pixel setting region 30. The first wall 160 is set between the dummy pixel setting region 30 and the frame glue setting region 20.

In the invention, the dummy pixel units 130 refer to the pixel units having no display function in the visible region 10, and the materials and the process of the dummy pixel units 130 are the same with those of the pixel units 120. Furthermore, in the invention, the pixel units 120 and the dummy pixel units 130 can be made at the same time, but the present invention is not limited thereto. For example, the pixel units 120 and the dummy pixel units 130 can also be made respectively at the different times. To apply the mask used in the process making the pixel units 120 to produce the dummy pixel units 130, avoiding designing another mask, preferably, the size of the dummy pixel unit 130 is the same with the size of the pixel unit 120, but the present invention is not limited thereto. For example, in the case that the pixel units 120 and the dummy pixel units 130 are made respectively at the different times, another mask can be designed to produce the dummy pixel units 130 which have arbitrary size and meet the requirements.

Further, the CF substrate 200 comprises a plurality of light-shielding units (e.g. black matrix) 220 and a transparent conductive film (e.g. an ITO conductive film) 230. The light-shielding units 220 are disposed between the transparent substrate 210 and the pixel units 120, and each of the light-shielding units 220 corresponds to a position between two of the pixel units 120. The transparent conductive film 230 is disposed on the pixel units 120.

The TFT substrate 100 includes a transparent substrate (e.g. a glass substrate) 110, a plurality of thin film transistors 140, and a peripheral circuit 150. The thin film transistors 140 are disposed on the transparent substrate 110 and corresponds to the visual region 10 of the CF substrate 200. The peripheral circuit 150 is disposed on the transparent substrate 110 and corresponds to a position between the visual region 10 and the dummy pixel setting region 30 of the CF substrate 200.

The third embodiment of the present invention prevents the PI liquid from overflow to the frame glue setting region 20 by setting the first wall 160 between the dummy pixel setting region 30 and the frame glue setting region 20 when forming an alignment film (Polyimide, PI) in the visual region 10. It avoids the abnormal situation happening when coating the frame glue in the frame glue setting region 20 and the waste of the PI liquid, and improves the stability of the LCD panel. Moreover, by setting the dummy pixel setting region 30 and the dummy pixel units 130 in the dummy pixel setting region 30, the present invention greatly improves the accuracy in controlling PI, avoids the problems caused by the difficulty in controlling the accuracy of PI, e.g. Mura, and improves the product yield.

### The Fourth Embodiment

FIG. 5 is a cross-sectional view of a LCD panel according to the fourth embodiment of the present invention.

Please refer to FIG. 5, the difference with the LCD panel according to the third embodiment of the present invention is described as below:

In the LCD panel according to the fourth embodiment of the present invention, the TFT substrate 100 further comprises a second wall 170. The second wall is set on the transparent substrate 110 and corresponds to a position between the dummy pixel setting region 30 and the frame glue setting region 20 of the transparent substrate 210 of the CF panel 200. When the TFT substrate 100 and the CF substrate 200 are bonded together, the first wall 160 and the second wall 170 are staggered so as to enhance the capacity to block the PI liquid from spilling to the frame glue setting region 20.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A liquid crystal display panel comprising a display substrate, wherein the display substrate includes a transparent substrate, a plurality of pixel units, a plurality of dummy pixel units, and a first wall, the transparent substrate includes a visual region, a dummy pixel setting region located outside the visible region, and a frame glue setting region located outside the dummy pixel setting region, the pixel units are disposed on the transparent substrate in the visual region, the dummy pixel units are disposed on the transparent substrate in the dummy pixel setting region, and the first wall is set on the transparent substrate between the dummy pixel setting region and the frame glue setting region.

2. The liquid crystal display panel of claim 1, wherein the size of the dummy pixel unit and the size of the pixel unit are the same.

3. The liquid crystal display panel of claim 1, wherein the display substrate is a thin film transistor array substrate including a plurality of thin film transistors and a peripheral circuit, the thin film transistors are disposed between the transparent substrate and the pixel units in the visible region, and the peripheral circuit is disposed on the transparent substrate between the visible region and the dummy pixel setting region.

4. The liquid crystal display panel of claim 2, wherein the display substrate is a thin film transistor array substrate including a plurality of thin film transistors and a peripheral circuit, the thin film transistors are disposed between the transparent substrate and the pixel units in the visible region, and the peripheral circuit is disposed on the transparent substrate between the visible region and the dummy pixel setting region.

5. The liquid crystal display panel of claim 3, further comprising another display substrate, wherein the another display substrate is a color filter substrate comprising another transparent substrate, a plurality of light-shielding units, a transparent conductive film, an insulating layer and a second wall, the light-shielding units are disposed on the another transparent substrate, each of the light-shielding units corresponds to a position between two of the pixel units, the transparent conductive film is disposed on the light-shielding units, the insulating layer is disposed between the transparent conductive film and the light-shielding units, and the second wall is set on the another transparent substrate and corresponds to a position between the dummy pixel setting region and the frame glue setting region.

6. The liquid crystal display panel of claim 4, further comprising another display substrate, wherein the another display substrate is a color filter substrate comprising another transparent substrate, a plurality of light-shielding units, a transparent conductive film, an insulating layer and a second wall, the light-shielding units are disposed on the another transparent substrate, each of the light-shielding units corresponds to a position between two of the pixel units, the transparent conductive film is disposed on the light-shielding units, the insulating layer is disposed between the transparent conductive film and the light-shielding units, and the second wall is set on the another transparent substrate and corresponds to a position between the dummy pixel setting region and the frame glue setting region.

7. The liquid crystal display panel of claim 1, wherein the display substrate is a color filter substrate including a plurality of light-shielding units and a transparent conductive film, the light-shielding units are disposed between the transparent substrate and the pixel units, each of the light-shielding units corresponds to a position between two of the pixel units, and the transparent conductive film is disposed on the pixel units.

8. The liquid crystal display panel of claim 2, wherein the display substrate is a color filter substrate including a plurality of light-shielding units and a transparent conductive film, the light-shielding units are disposed between the transparent substrate and the pixel units, each of the light-shielding units corresponds to a position between two of the pixel units, and the transparent conductive film is disposed on the pixel units.

9. The liquid crystal display panel of claim 7, further comprising another display substrate, wherein the another display substrate is a thin film transistor array substrate including another transparent substrate, a plurality of thin film transistors, a peripheral circuit, and a second wall, the thin film transistors are disposed on the another transparent substrate and corresponds to the visual region, the peripheral circuit is disposed on the another transparent substrate and corresponds to a position between the visual region and the dummy pixel setting region, and the second wall is set on the another transparent substrate and corresponds to a position between the dummy pixel setting region and the frame glue setting region.

10. The liquid crystal display panel of claim 10, further comprising another display substrate, wherein the another display substrate is a thin film transistor array substrate including another transparent substrate, a plurality of thin film transistors, a peripheral circuit, and a second wall, the thin film transistors are disposed on the another transparent substrate and corresponds to the visual region, the peripheral circuit is disposed on the another transparent substrate and corresponds to a position between the visual region and the dummy pixel setting region, and the second wall is set on the another transparent substrate and corresponds to a position between the dummy pixel setting region and the frame glue setting region.

11. A thin film transistor array substrate comprising a transparent substrate, a plurality of pixel units, a plurality of dummy pixel units, and a first wall, wherein the transparent substrate includes a visual region, a dummy pixel setting region located outside the visible region, and a frame glue setting region located outside the dummy pixel setting region, the pixel units are disposed on the transparent substrate in the visual region, the dummy pixel units are disposed on the transparent substrate in the dummy pixel setting region, and the first wall is set on the transparent substrate between the dummy pixel setting region and the frame glue setting region.

12. The thin film transistor array substrate of claim 11, further comprising a plurality of thin film transistors and a peripheral circuit, wherein the thin film transistors are disposed between the transparent substrate and the pixel units in the visual region, and the peripheral circuit is disposed on the transparent substrate between the visual region and the dummy pixel setting region.

13. A color filter substrate comprising a transparent substrate, a plurality of pixel units, a plurality of dummy pixel units, and a first wall, wherein the transparent substrate includes a visual region, a dummy pixel setting region located outside the visible region, and a frame glue setting region located outside the dummy pixel setting region, the pixel units are disposed on the transparent substrate in the visual region, the dummy pixel units are disposed on the transparent substrate in the dummy pixel setting region, and the first wall is set on the transparent substrate between the dummy pixel setting region and the frame glue setting region.

14. The color filter substrate of claim 14, further comprising a plurality of light-shielding units and a transparent conductive film, wherein the light-shielding units are disposed between the transparent substrate and the pixel units, each of the light-shielding units corresponds to a position between two of the pixel units, and the transparent conductive film is disposed on the pixel units.
